(19) United States
(12) Patent Application Publication
(10) Pub. No.: US 2025/0386589 A1
(43) Pub. Date: Dec. 18, 2025

(54) STACKED NANOSHEET CAPACITOR-TRANSISTOR DEVICE

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Julien Frougier, Albany, NY (US)

(21) Appl. No.: 18/743,276

(22) Filed: Jun. 14, 2024

(51) Int. Cl. H01L 27/06; H01L 23/528; H01L 29/06; H01L 29/40; H01L 29/417; H01L 29/423; H01L 29/66; H01L 29/775; H01L 29/786

(52) U.S. Cl. CPC H10D 84/811; H01L 23/5286; H10D 1/692; H10D 30/014; H10D 30/031; H10D 30/43; H10D 30/6729; H10D 30/6735; H10D 30/6757; H10D 62/121; H10D 64/01; H10D 64/017

(57) ABSTRACT

A semiconductor device includes at least one metal-insulator-metal capacitor device, where the metal-insulator-metal capacitor device comprises a first electrode, an insulator material surrounding the first electrode, and a second electrode surrounding the insulator material. The semiconductor device includes at least one transistor device vertically adjacent to the at least one metal-insulator-metal capacitor device, and a first middle-of-line contact connecting the first electrode to a first source/drain region associated with the at least one transistor device and to at least one first frontside interconnect structure.

### BACKGROUND

In semiconductor device manufacturing, capacitors are passive circuit components that are utilized in integrated circuity of a semiconductor chip for various purposes. For example, capacitors can be utilized to decouple power supplies, to form memory elements, to form resistor-capacitor (RC) delay circuits or provide various other circuit functions. While many types of capacitor structures can be utilized, metal-insulator-metal (MIM) capacitors are commonly used for analog, microwave, and radio frequency (RF) applications. In general, planar MIM capacitors are comprised of two metallic plates separated by an insulator layer.

### SUMMARY

Embodiments described herein provide techniques for forming stacked nanosheet capacitor-transistor devices.

In one embodiment, a semiconductor device includes at least one metal-insulator-metal capacitor device, where the metal-insulator-metal capacitor device includes a first electrode, an insulator material surrounding the first electrode, and a second electrode surrounding the insulator material. The semiconductor device also includes at least one transistor device vertically adjacent to the at least one metal-insulator-metal capacitor device, and a first middle-of-line contact connecting the first electrode to a first source/drain region associated with the at least one transistor device and to at least one first frontside interconnect structure.

In another embodiment, a semiconductor device includes a transistor device associated with first and second source/drain regions, a capacitor device vertically adjacent to the transistor device. The capacitor device includes a first electrode, an insulator material surrounding the first electrode, and a second electrode surrounding the insulator material, where the first electrode comprises one or more stacked first portions and at least one second portion that is larger than each of the one or more first portions. The semiconductor device also includes a middle-of-line contact connecting the first electrode to the first source/drain region.

In another embodiment, a method includes forming a capacitor device in a first portion of a stacked nanosheet structure, where the capacitor device comprises a first electrode, an insulator material surrounding the first electrode, and a second electrode surrounding the insulator material. The method includes forming a transistor device in a second portion of the stacked nanosheet structure includes one or more channel layers, where the first portion and the second portion of the nanosheet structure. The method also includes forming a direct backside source/drain contact that connects a first source/drain region of the transistor device to one or more backside interconnect structures.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X and Y on which the cross-sectional views of FIGS. 2A-20B are based, according to an illustrative embodiment.

FIG. 2A depicts a first cross-sectional view corresponding to line X in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line Y in FIG. 1 illustrating the semiconductor structure of FIG. 1 during an intermediate step of a method of fabricating a nanosheet transistor structure, according to an illustrative embodiment.

FIG. 3A depicts a first cross-sectional view corresponding to the line X in FIG. 1 following spacer formation, according to an illustrative embodiment.

FIG. 3B depicts a second cross-sectional view corresponding to the line Y in FIG. 1 following the spacer formation, according to an illustrative embodiment.

FIG. 4A depicts a first cross-sectional view corresponding to the line X in FIG. 1 following partial removal of an organic planarization layer (OPL) and spacer patterning, according to an illustrative embodiment.

FIG. 4B depicts a second cross-sectional view corresponding to the line Y in FIG. 1 following the partial removal of the organic planarization layer (OPL) and spacer patterning, according to an illustrative embodiment.

FIG. 5A depicts a first cross-sectional view corresponding to the line X in FIG. 1 following OPL and hardmask (HM) removal, and dummy gate formation, according to an illustrative embodiment.

FIG. 5B depicts a second cross-sectional view corresponding to the line Y in FIG. 1 following the OPL and HM removal, and the dummy gate formation, according to an illustrative embodiment.

FIG. 6A depicts a first cross-sectional view corresponding to the line X in FIG. 1 following sacrificial layer removal and gate spacer removal, and bottom and middle dielectric layer formation and spacer dielectric formation, according to an illustrative embodiment.

FIG. 6B depicts a second cross-sectional view corresponding to the line Y in FIG. 1 following the sacrificial layer removal and the gate spacer removal, and the bottom and middle dielectric layer formation and spacer dielectric formation, according to an illustrative embodiment.

FIG. 7A depicts a first cross-sectional view corresponding to the line X in FIG. 1 following nanosheet recessing, inner spacer formation, placeholder formation, source/drain region formation, and interlayer dielectric (ILD) layer formation, according to an illustrative embodiment.

FIG. 7B depicts a second cross-sectional view corresponding to the line Y in FIG. 1 following the nanosheet recessing, the inner spacer formation, the placeholder formation, the source/drain region formation, and the ILD layer formation, according to an illustrative embodiment.

FIG. 8A depicts a first cross-sectional view corresponding to the line X in FIG. 1 following a poly open chemical mechanical planarization (CMP) (POC) process, dummy gate removal, sacrificial layer removal, high-k (HK) layer deposition, and reliability annealing, according to an illustrative embodiment.

FIG. 8B depicts a second cross-sectional view corresponding to the line Y in FIG. 1 following the POC process, the dummy gate removal, the sacrificial layer removal, the HK layer deposition, and the reliability annealing, according to an illustrative embodiment.

FIG. 9A depicts a first cross-sectional view corresponding to the line X in FIG. 1 following work function metal (WFM) formation, according to an illustrative embodiment.

FIG. 9B depicts a second cross-sectional view corresponding to the line Y in FIG. 1 following the WFM formation, according to an illustrative embodiment.

FIG. 10A depicts a first cross-sectional view corresponding to the line X in FIG. 1 following ILD etch back, selective source/drain region and channel layer removal, according to an illustrative embodiment.

FIG. 10B depicts a second cross-sectional view corresponding to the line Y in FIG. 1 following the ILD etch back, the selective source/drain region and channel layer removal, according to an illustrative embodiment.

FIG. 11A depicts a first cross-sectional view corresponding to the line X in FIG. 1 following selective inner spacer removal, according to an illustrative embodiment.

FIG. 11B depicts a second cross-sectional view corresponding to the line Y in FIG. 1 following the selective inner spacer removal, according to an illustrative embodiment.

FIG. 12A depicts a first cross-sectional view corresponding to the line X in FIG. 1 following removal of exposed portions of the HK layer and additional HK layer deposition, according to an illustrative embodiment.

FIG. 12B depicts a second cross-sectional view corresponding to the line Y in FIG. 1 following the removal of exposed portions of the HK layer and the additional HK layer deposition, according to an illustrative embodiment.

FIG. 13A depicts a first cross-sectional view corresponding to the line X in FIG. 1 following MIM capacitor top metal electrode fill and CMP, according to an illustrative embodiment.

FIG. 13B depicts a second cross-sectional view corresponding to the line Y in FIG. 1 following the MIM capacitor top metal electrode fill and the CMP, according to an illustrative embodiment.

FIG. 14A depicts a first cross-sectional view corresponding to the line X in FIG. 1 following shallow and deep gate cut patterning and dielectric fill, according to an illustrative embodiment.

FIG. 14B depicts a second cross-sectional view corresponding to the line Y in FIG. 1 following the shallow and deep gate cut patterning and dielectric fill, according to an illustrative embodiment.

FIG. 15A depicts a first cross-sectional view corresponding to the line X in FIG. 1 following middle-of-line (MOL) deep contact patterning, according to an illustrative embodiment.

FIG. 15B depicts a second cross-sectional view corresponding to the line Y in FIG. 1 following the MOL deep contact patterning, according to an illustrative embodiment.

FIG. 16A depicts a first cross-sectional view corresponding to the line X in FIG. 1 following MOL shallow contact and gate patterning and metallization, according to an illustrative embodiment.

FIG. 16B depicts a second cross-sectional view corresponding to the line Y in FIG. 1 following the MOL shallow contact and gate patterning and metallization, according to an illustrative embodiment.

FIG. 17A depicts a first cross-sectional view corresponding to the line X in FIG. 1 following back-end-of-line (BEOL) interconnect formation and carrier wafer bonding, according to an illustrative embodiment.

FIG. 17B depicts a second cross-sectional view corresponding to the line Y in FIG. 1 following the BEOL interconnect formation and the carrier wafer bonding, according to an illustrative embodiment.

FIG. 18A depicts a first cross-sectional view corresponding to the line X in FIG. 1 following wafer flipping, semiconductor substrate removal, etch stop layer removal, and backside ILD layer formation, according to an illustrative embodiment.

FIG. 18B depicts a second cross-sectional view corresponding to the line Y in FIG. 1 following the wafer flipping, the semiconductor substrate removal, the etch stop layer removal, and the backside ILD layer formation, according to an illustrative embodiment.

FIG. 19A depicts a first cross-sectional view corresponding to the line X in FIG. 1 following backside contact patterning and placeholder removal, according to an illustrative embodiment.

FIG. 19B depicts a second cross-sectional view corresponding to the line Y in FIG. 1 following the backside contact patterning and the placeholder removal, according to an illustrative embodiment.

FIG. 20A depicts a first cross-sectional view corresponding to the line X in FIG. 1 following backside contact and backside interconnect formation, according to an illustrative embodiment.

FIG. 20B depicts a second cross-sectional view corresponding to the line Y in FIG. 1 following the backside contact and the backside interconnect formation, according to an illustrative embodiment.

FIG. 21 depicts a top view of a semiconductor structure with line X on which the cross-sectional views of FIGS. 22-23 are based, according to an illustrative embodiment.

FIG. 22 depicts a cross-sectional view corresponding to the line X in FIG. 21 of a semiconductor structure having a unit cell comprising one transistor and two capacitors, according to an illustrative embodiment.

FIG. 23 depicts a cross-sectional view corresponding to the line X in FIG. 21 of semiconductor structure having a unit cell comprising one transistor and five capacitors, according to an illustrative embodiment.

### DETAILED DESCRIPTION

Illustrative embodiments are described herein in the context of illustrative methods for stacked device structures with split device layers, along with illustrative apparatus, systems and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm and beyond), next generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation SFET devices.

Although embodiments described herein are discussed in connection with nanosheet stacks, the embodiments are not necessarily limited thereto, and may similarly apply to nanowire stacks.

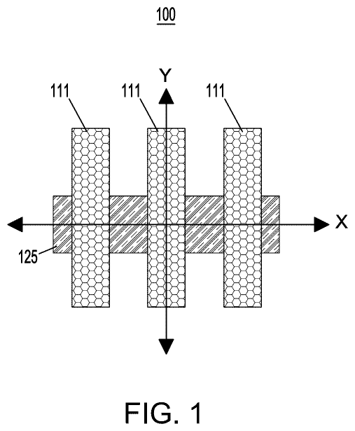

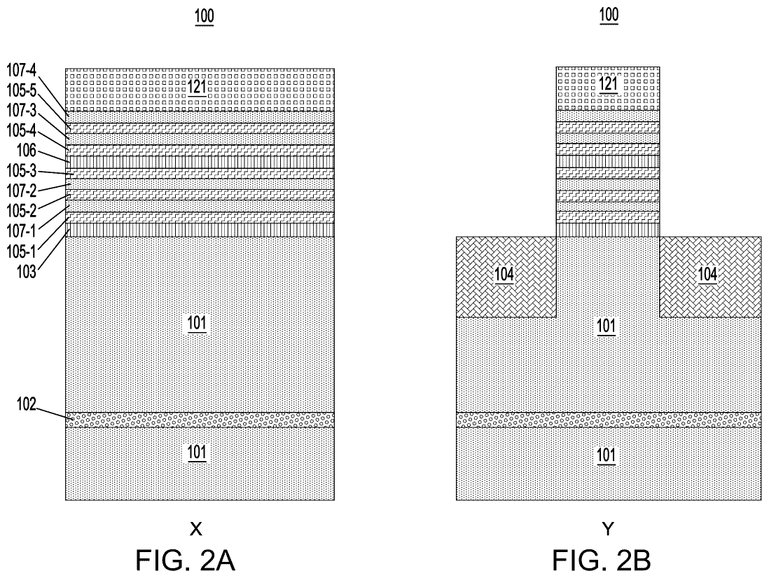

Referring to FIG. 1 and to the cross-sectional views in FIGS. 2A and 2B, which respectively correspond to the lines X and Y in FIG. 1, a semiconductor structure 100 includes a stacked structure of sacrificial layers 105-1, 105-2, 105-3, 105-4, and 105-5 (collectively “sacrificial layers 105”) and channel layers 107-1, 107-2, 107-3, and 107-4 (collectively “channel layers 107”). In an illustrative embodiment, the sacrificial layers 105 comprise SiGe and the channel layers 107 comprise silicone.

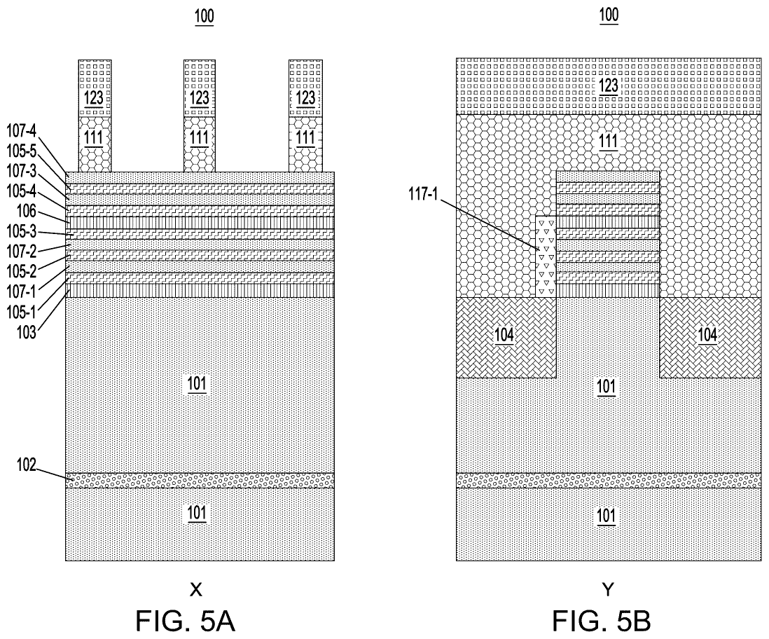

The stacked structure also includes two additional sacrificial layers 103 and 106. The sacrificial layers 103 and 106 can be formed of SiGe with a different concentration of germanium than that of the sacrificial layers 105. For example, the additional sacrificial layers 103 and 106 can have, but are not necessarily limited to, a germanium concentration of about 60% (for example, SiGe60). As explained in more detail herein, the additional sacrificial layers 103 and 106 have a different concentration of germanium than the sacrificial layers 105 so that remaining portions of the additional sacrificial layer 103 can be selectively etched and removed with respect to the sacrificial layers 105 when forming bottom dielectric isolation (BDI) and middle dielectric isolation (MDI) layers (see, for example, FIGS. 5A and 5B, including BDI layers 109 and MDI layers 110).

While five sacrificial layers 105 and four channel layers 107 are shown, embodiments described herein are not necessarily limited to the shown number of sacrificial layers 105 and channel layers 107, and there may be more or less layers in the same alternating configuration depending on design constraints. The sacrificial layers 105, as described further herein, are eventually removed, and replaced by gate structures.

The sacrificial layers 103, 105, and 106 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”)

An etch stop layer 102 is formed within the semiconductor substrate 101. The etch stop layer 102 may comprise a buried oxide (BOX) layer or SiGe, or another suitable material such as a III-V semiconductor epitaxial layer.

A hardmask (HM) layer 121 is formed on top of the topmost channel layer 107-4 using any conventional deposition technique such as physical vapor deposition (PVD), atomic layer deposition (ALD), chemical vapor deposition (CVD), etc., followed by a planarization step such as a CMP process. The HM layer 121 can be formed of any suitable material such as, for example, amorphous silicon, or another suitable material.

Portions of the nanosheet stacks comprising the sacrificial layers 105 and 106, and the channel layers 107 have been removed, and portions of the additional sacrificial layer 103 and the semiconductor substrate 101 are recessed to form isolation regions 104 (for example, shallow trench isolation (STI)) regions, as shown.

The isolation regions 104 can comprise a dielectric material fill in the recessed portions of the semiconductor substrate 101 and the vacant areas left by the removal of the portions of the additional sacrificial layer 103 and the semiconductor substrate 101. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof, and is deposited using deposition techniques such as, for example, CVD, plasma enhanced CVD (PECVD), radio-frequency CVD (RFCVD), PVD, ALD, molecular beam deposition (MBD), pulsed laser deposition (PLD), and/or liquid source misted chemical deposition (LSMCD).

In the example shown in FIG. 2B one nanosheet stack is shown, which includes sacrificial layers 103, 105, and 106, and stacked channel layers 107. However, it is to be appreciated that there may be two or more nanosheet stacks in other embodiments.

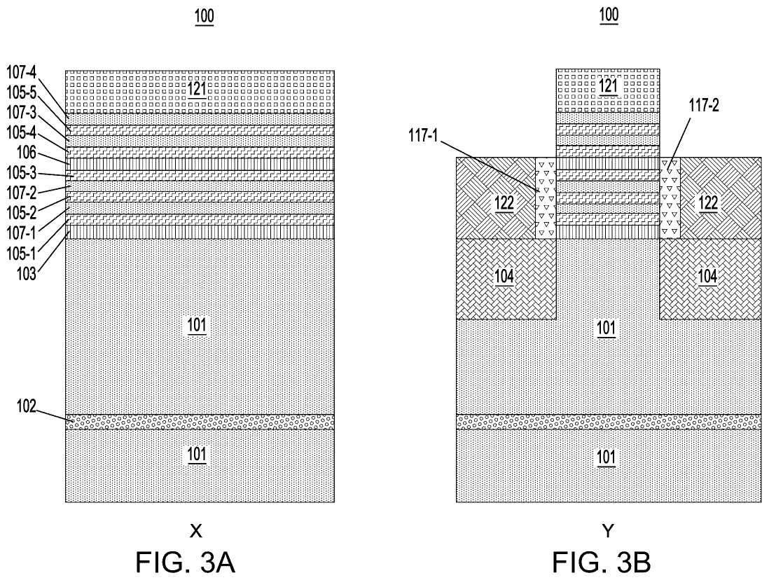

Referring to FIGS. 3A and 3B, spacers 117-1 and 117-2 are formed on the sidewalls of the sacrificial layers 105-1, 105-2, and 105-3, the additional sacrificial layers 103, 106, and the channel layers 107-1 and 107-2. In some embodiments, the spacers 117-1 and 117-2 are formed using a conformal layer of spacer material, followed by an anisotropic etch process to remove horizontal portions of the layer of spacer material and reduce the height of the vertical portions of the spacer layer to define spacers 117-1 and 117-2. The height of the spacers 117-1 and 117-2 can be controlled such that their upper surfaces at least partially overlap the additional sacrificial layer 106, as shown in FIG. 3B. A mask layer 122 (e.g., organic patterning layer (OPL)) is formed to cover the exposed side surfaces of the spacers 117-1 and 117-2, as shown in FIG. 3B.

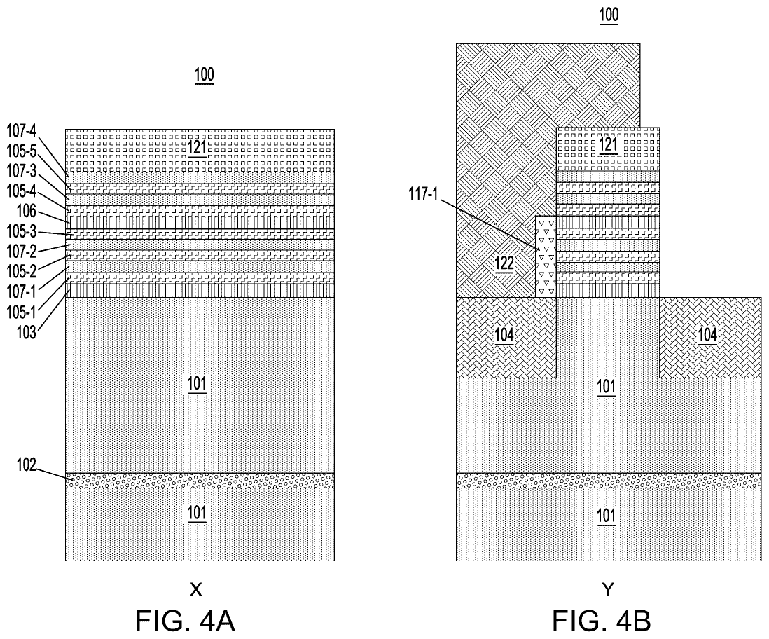

Referring to FIGS. 4A and 4B, additional material is added to the mask layer 122 so that it is formed above the stacked structure comprising the sacrificial layers 103, 105, 106, and the channel layers 107. The mask layer 122 is then patterned to cover the left portion and expose the right portion of the stacked structure, thereby exposing a portion of the spacer 117-2. An etch process is subsequently performed to remove the portion of the spacer 117-2, as shown in FIG. 4B.

Referring to FIGS. 5A and 5B, the semiconductor structure 100 is shown following the removal of the HM layer 121 and the mask layer 122, and the formation of dummy gate portions 111 and a gate HM layer 123. The dummy gate portions 111 can be formed on the uppermost channel layers 107-4 and around the stacked structure comprising the sacrificial layers, 103, 105, 106, the channel layers 107, and the spacer 117-1. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as CMP, and lithography and etching steps to remove excess dummy gate material and pattern the deposited layer. The gate HM layer 123 is formed on the dummy gate portions 111. The gate HM layer 123 comprise, for example, a nitride such as SiN or other nitride materials.

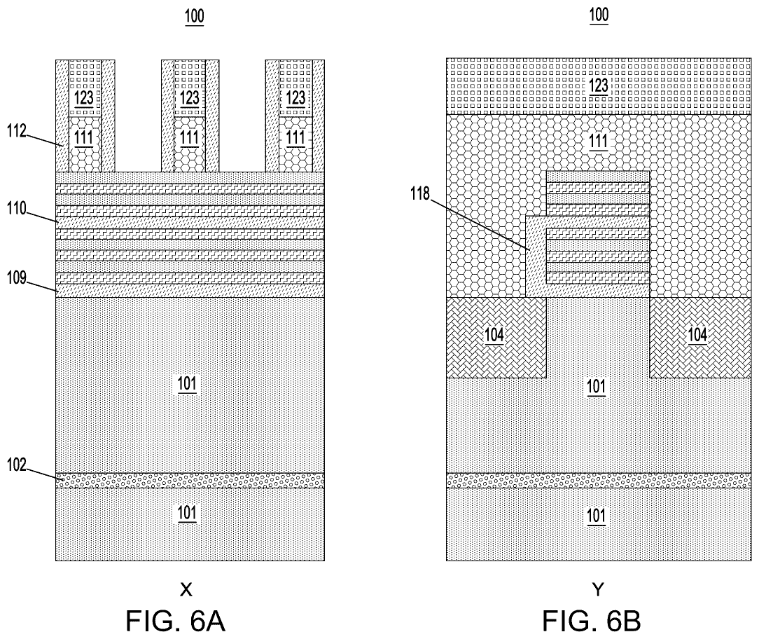

Referring to FIGS. 6A and 6B, the additional sacrificial layers 103 and 106 and the spacer 117-1 are removed using, for example, an aqueous solution containing ammonium hydroxide (NH₄OH) and hydrogen peroxide (H₂O₂), or a gas containing hydrogen fluoride (HF), to selectively etch the portions of the additional sacrificial layers 103 and 106, and the spacer 117-1 with respect to the portions of the semiconductor substrate 101, the sacrificial layers 105, and the channel layers 107. The selective etching removes the remaining portions of the additional sacrificial layers 103 and 106 to form vacant areas where the BDI layer 109 and the MDI layer 110 will be formed.

Following the removal of the additional sacrificial layers 103, 106, and the spacer 117-2, dielectric material is deposited in place of the remaining portions of the additional sacrificial layers 103, 106, and the spacer 117-2 using deposition techniques such as, for example, CVD, PECVD, RFCVD, PVD, ALD, MBD, PLD, and/or LSMCD, followed by an etch-back process to form the BDI layer 109, the MDI layer 110, and a spacer 118 in the corresponding vacant areas. The BDI layer 109 and the MDI layer 110, and the spacer 118 may comprise, for example, silicon oxide (SiOₓ), silicon oxycarbide (SiOC), SIN, SION, SiCN, BN, SiBCN, SiOCN or some other dielectric.

Additionally, gate spacers 112 are formed on the sides of the gate HM layer 123 and dummy gate portions 111 using one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the gate HM layer 123 and gate spacers 112 can be the same material or different materials. The gate spacers 112 can be formed by any suitable technique such as deposition followed by directional etching. Deposition may include but is not limited to ALD or CVD. Directional etching may include but is not limited to reactive ion etching (RIE).

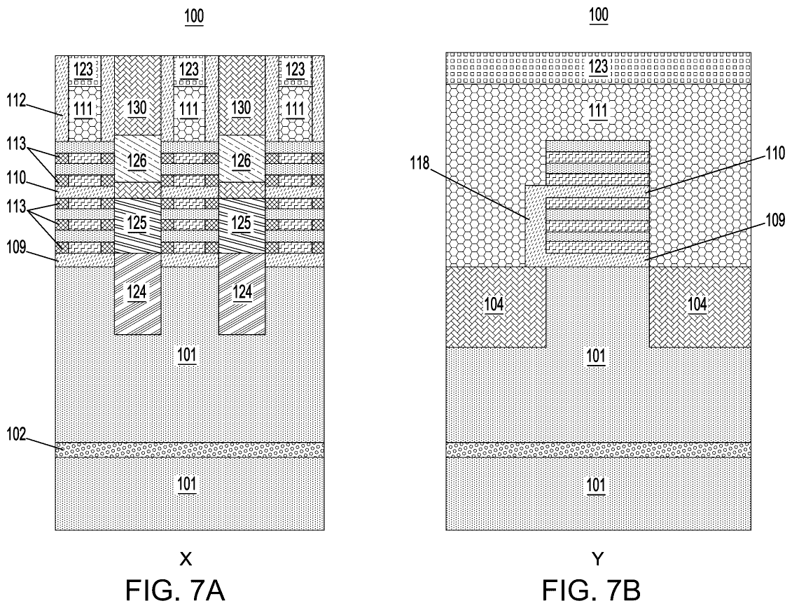

Referring to FIGS. 7A and 7B, exposed portions of the stacked sacrificial layers 105 and the channel layers 107, which are not under the gate HM layer 123, the gate spacers 112, and the dummy gate portions 111, are removed using, for example, an etching process, such as RIE, where the gate HM layer 123, the gate spacers 112, and the dummy gate portions 111 are used as a mask.

As can be seen in FIG. 7A, the portions of the stacked structures comprising the sacrificial layers 105 and the channel layers 107 under the gate HM layer 123, the gate spacers 112, and under the dummy gate portions 111 remain after the etching process, and portions of the sacrificial layers 105 and the channel layers 107 in areas that correspond to where source/drain regions will be formed are removed. Portions of the top surface of the BDI layer 109 on sides of the stacked structures comprising the sacrificial layers 105 and the channel layers 107 are exposed. Due to, for example, germanium in the sacrificial layers 105, lateral etching of the sacrificial layers 105 can be performed selectively with respect to the channel layers 107, such that the side portions of the sacrificial layers 105 can be removed to create vacant areas to be filled by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on opposite lateral sides of the dummy gate portions 111. In an illustrative embodiment, the gate spacers 112 are formed from the same or similar material as that of the inner spacers 113. Like the gate spacers 112, the inner spacers 113 can be formed by any suitable technique such as deposition followed by directional etching.

Exposed portions of the BDI layer 109 between the stacked structures comprising the sacrificial layers 105 and the channel layers 107 are removed in a first removal process. Following the removal of the exposed portions of the BDI layer 109 between the stacked structures comprising the sacrificial layers 105 and the channel layers 107, underlying portions of the semiconductor substrate 101 are removed, such that portions of the semiconductor substrate 101 are recessed to create trenches in the semiconductor substrate 101. The semiconductor substrate 101 can be etched using, for example, a tetramethyl ammonium hydroxide (TMAH) solution, to selectively remove SiGe having a relatively higher percentage of germanium, or CF₄ gas to selectively remove SiGe having a relatively lower percentage of germanium. The exposed portions of the semiconductor substrate 101 are recessed below the bottom surfaces of the remaining portions of the BDI layer 109.

The trenches are filled with sacrificial materials to form sacrificial placeholders 124. Bottom source/drain regions 125, and top source/drain regions 126, and an inter-layer dielectric (ILD) layer 130 are also formed. In illustrative embodiments, the sacrificial placeholders 124 can comprise, for example, SiGe, III-V semiconductor material, or other semiconductor materials. The sacrificial placeholders 124, the bottom source/drain regions 125, and the top source/drain regions 126 can be epitaxially grown in a bottom-up epitaxial growth process. For example, the sacrificial placeholders 124 can be grown from the exposed portions of the semiconductor substrate 101, and the bottom source/drain regions 125 can be epitaxially grown from the exposed surfaces of their corresponding sacrificial placeholders 124.

Side surfaces of respective ones of the channel layers 107 contact a side surface of at least one adjacent bottom source/drain region 125 or top source/drain region 126. The top surfaces of the top source/drain regions 126 are above the top surfaces of the uppermost ones of the channel layers 107.

The ILD layer 130 is deposited to fill in portions on and around the source/drain regions 125 and 126. The ILD layer 130 is deposited using deposition techniques such as, for example, CVD, PECVD, RFCVD, PVD, ALD, MBD, PLD, and/or LSMCD, followed by a planarization process, such as CMP, to remove excess portions of the ILD layer 130 deposited on top of the gate HM layer 123 and gate spacers 112. The ILD layer 130 may comprise, for example, SiOx, SiOC, SiOCN or some other dielectric.

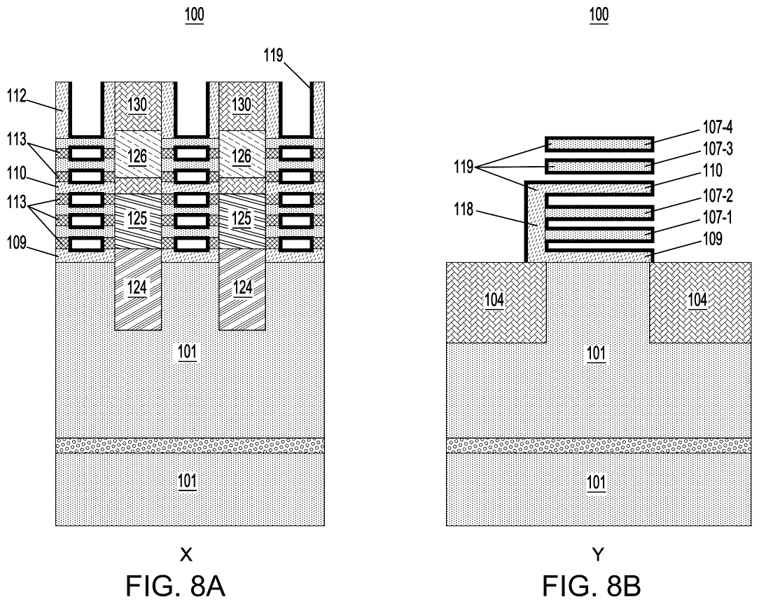

FIGS. 8A and 8B show cross-sectional views, which respectively correspond to the lines X and Y in FIG. 1, of the semiconductor structure 100 following the removal of the gate HM layer 123, the dummy gate portions 111, and the sacrificial layers 105. A planarization process, such as CMP, is used to remove the gate HM layer 123 and parts of the gate spacers 112 to expose the dummy gate portions 111.

The dummy gate portions 111 and the sacrificial layers 105 are selectively removed to create vacant areas. For example, the dummy gate portions 111 can be selectively removed using hot ammonia to remove a-Si, and the sacrificial layers 105 can be selectively removed with respect to the channel layers 107 using, for example, a dry HCI etch. Following the removal of the dummy gate portions 111 and the sacrificial layers 105, the channel layers 107 are suspended.

A first dielectric liner 119 is formed using conformal deposition of a dielectric material that is deposited over exposed vertical and horizontal surfaces of the channel layers 107, the spacer 118, the BDI layer 109, and the MDI layer 110. The first dielectric liner 119 is formed of an HK dielectric material. For example, in some embodiments, the first dielectric liner 119 is formed of a metal oxide such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate, or any suitable HK dielectric material suitable for use as a dielectric layer in a MIM capacitor. In some embodiments, a reliability anneal process is performed to densify and crystallize the first dielectric liner 119.

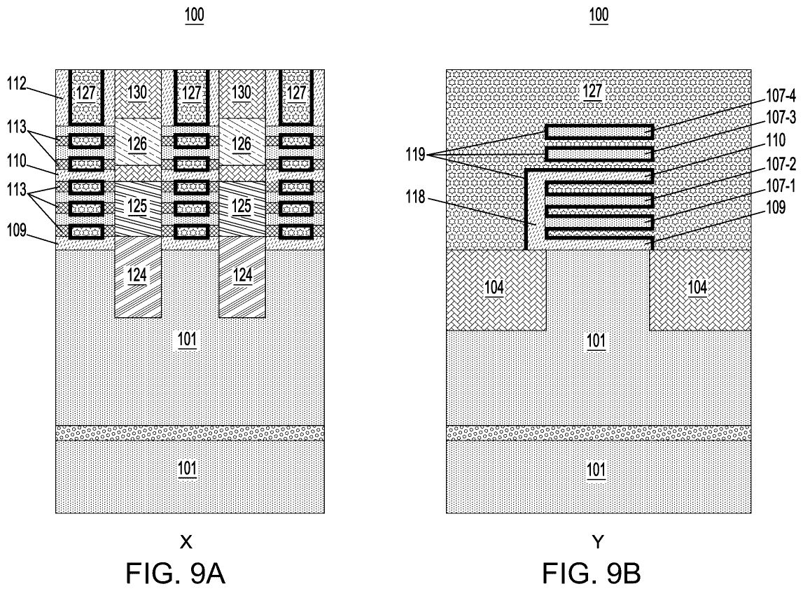

FIGS. 9A and 9B show cross-sectional views, which respectively correspond to lines X and Y in FIG. 1, of the semiconductor structure 100 following the formation of a first metal electrode layer 127. The first metal electrode layer 127 can include, but is not necessarily limited to, a work-function metal (WFM), such as titanium nitride (TiN), tantalum nitride (TaN) or ruthenium (Ru), TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the first dielectric liner 119. The first metal electrode layer 127 is deposited using deposition techniques such as CVD, PVD, ALD, electroplating, or another capacitor metal deposition method. The first metal electrode layer 127 covers the first dielectric liner 119. A CMP process can remove excess material of the first metal electrode layer 127 from the top surfaces of the ILD layer 130, the gate spacers 112, and the first dielectric liner 119. In some cases, small portions of the top surfaces of the ILD layer 130, the gate spacers 112, and the first dielectric liner 119 are also removed by the CMP.

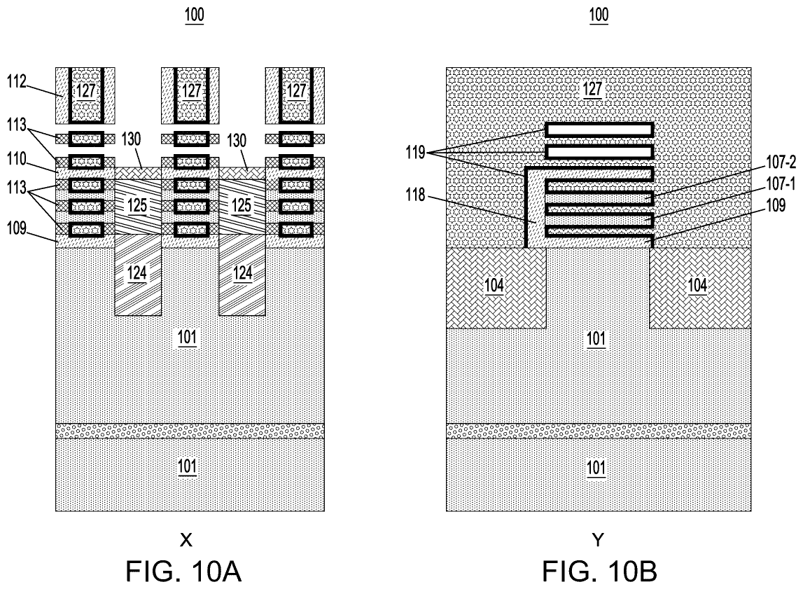

FIGS. 10A and 10B show cross-sectional views, which respectively correspond to the lines X and Y in FIG. 1, of the semiconductor structure 100 following etching of the ILD layer 130, selective removal of source/drain regions 126 and channel layers 107-3 and 107-4, according to an illustrative embodiment. Portions of the ILD layer 130 can be removed using, for example, a dry etch process using a RIE or ion beam etch (IBE) process, a wet chemical etch process, or a combination of these etching processes. Following the removal of portions of the ILD layer 130, top surfaces of the source/drain regions 126 are exposed. The source/drain regions 126 and the channel layers 107-3 and 107-are then removed using, for example, a dry etch process.

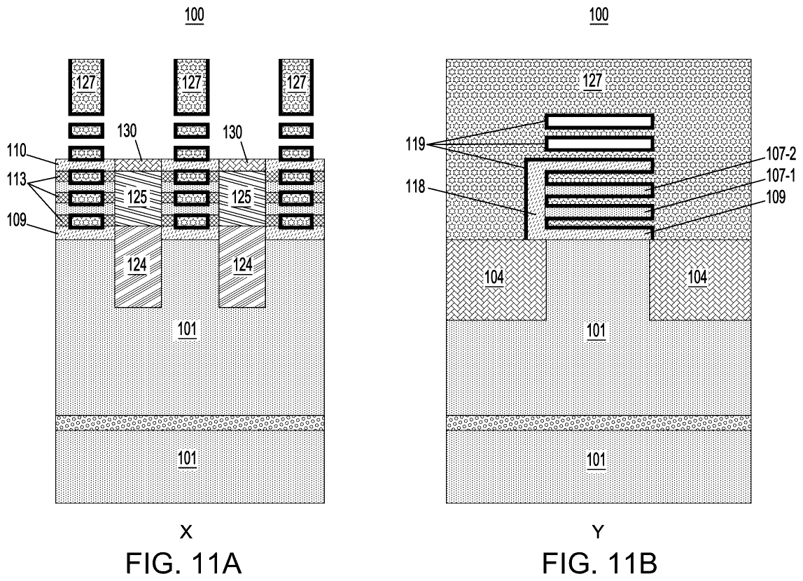

FIGS. 11A and 11B show cross-sectional views, which respectively correspond to the lines X and Y in FIG. 1, of the semiconductor structure 100 following removal of the gate spacer 112 and the inner spacers 113 positioned above the MDI layer 110. The gate spacer 112 and the inner spacers 113 can be removed using a dry etch process using a RIE or IBE, a wet chemical etch process, or a combination of these etching processes.

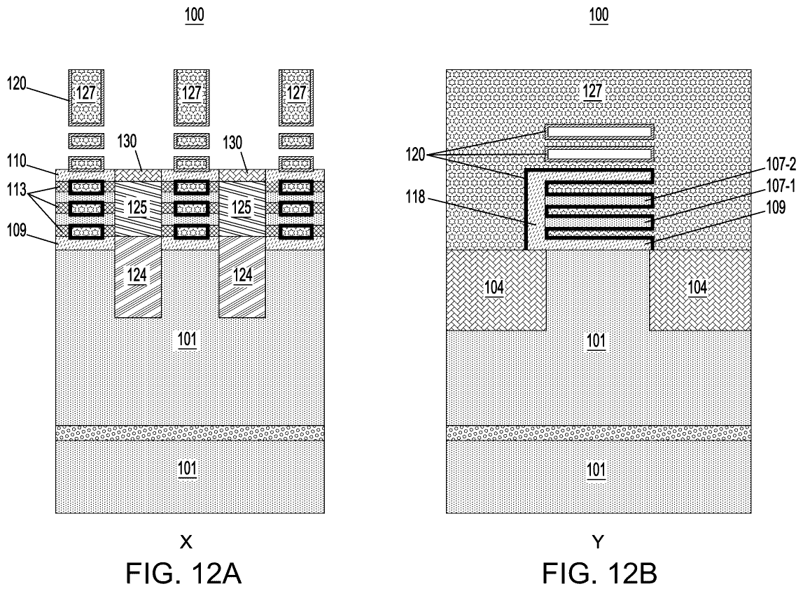

FIGS. 12A and 12B show cross-sectional views, which respectively correspond to the lines X and Y in FIG. 1, of the semiconductor structure 100 following the removal of exposed portions of the first dielectric liner 119 and deposition of a second dielectric liner 120 for a MIM capacitor. The process and materials used for forming the second dielectric liner 120 are similar to those used for forming the first dielectric liner 119.

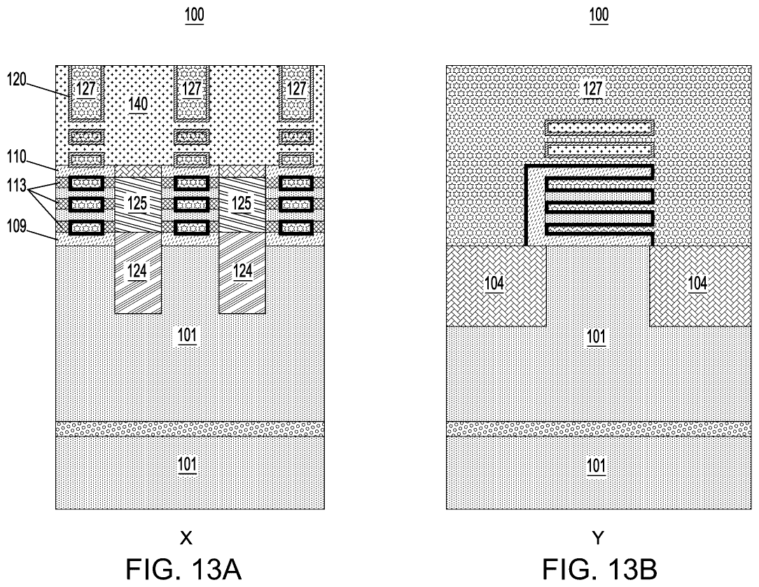

FIGS. 13A and 13B show cross-sectional views, which respectively correspond to the lines X and Y in FIG. 1, of the semiconductor structure 100 following MIM capacitor top metal electrode fill and planarization. A second metal electrode layer 140 is deposited in the vacant areas above the MDI layer 110 and the remaining portion of the ILD layer 130, as shown in FIGS. 13A and 13B. In one embodiment, the second metal electrode layer 140 is formed of the same metallic material as the first metal electrode layer 127. For instance, the second metal electrode layer 140 can be formed of TiN or AIN, or other metallic materials which are suitable for fabricating MIM capacitor electrodes. In another embodiment, the second metal electrode layer 140 can be formed of a metallic material different from that of the first metal electrode layer 127. As can be seen in FIG. 13A and 13B, the second metal electrode layer 140 is deposited to cover exposed portions of the second dielectric liner 120. A CMP process can remove excess material of the second metal electrode layer 140 from the top surfaces of the first metal electrode layer 127 and the second dielectric liner 120. The first metal electrode layer 127, the second dielectric liner 120, and the second metal electrode layer 140 can correspond to a MIM capacitor device.

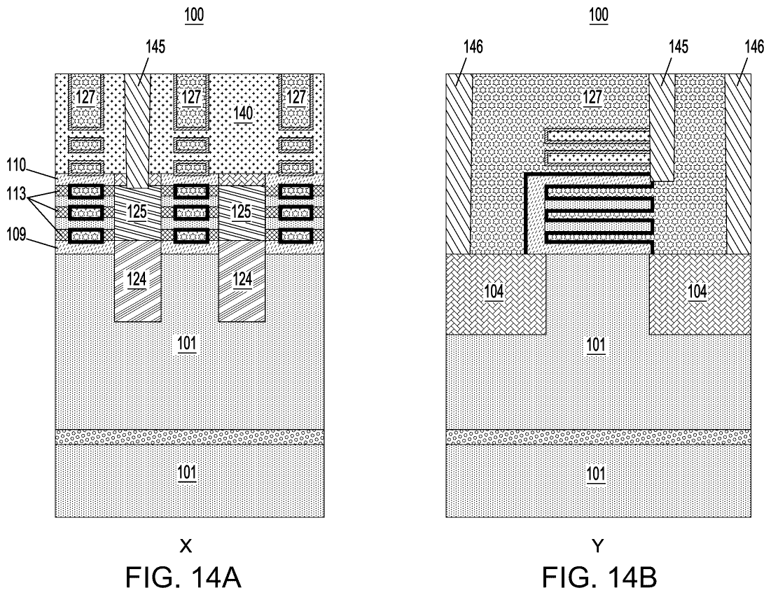

FIGS. 14A and 14B show cross-sectional views, which respectively correspond to the lines X and Y in FIG. 1, of the semiconductor structure 100 following shallow and deep gate cut patterning and dielectric fill, according to an illustrative embodiment. Shallow dielectric regions 145 (also referred to as shallow gate cut regions) are formed by etching (e.g., using RIE) the first metal electrode layer 127 to form a via that extends down to and contacts the second metal electrode layer 140 and the MDI layer 110, which are then filled with dielectric material, as shown. The dielectric material can be filled using deposition techniques such as, for example, CVD, PECVD, RFCVD, PVD, ALD, MBD, PLD, and/or LSMCD, followed by a planarization process, such as CMP, to remove excess portions of the dielectric material deposited on the top surfaces of the first metal electrode layer 127, the second metal electrode layer 140, and the second dielectric liner 120. The dielectric material of the shallow dielectric region 145 may comprise, but is not necessarily limited to, SiN, SiC, SiON, SiOC, SiCN, BN, SiBN, SiBCN, SiOCN, SiOₓ or some other dielectric. The shallow dielectric region 145 isolates the first and second electrodes of the MIM capacitor from a portion of the first metal electrode layer 127 that is used as a gate for a bottom transistor device corresponding to the channel layers 107-1 and 107-2.

Deep dielectric regions 146 (also referred to as deep gate cut regions) are formed in the second metal electrode layer 140 that extend down to and contact respective portions of the isolation regions 104. The deep dielectric regions 146 can be formed using similar materials and processes as the shallow dielectric regions 145. The deep dielectric regions 146 can isolate gates of neighboring bottom transistors.

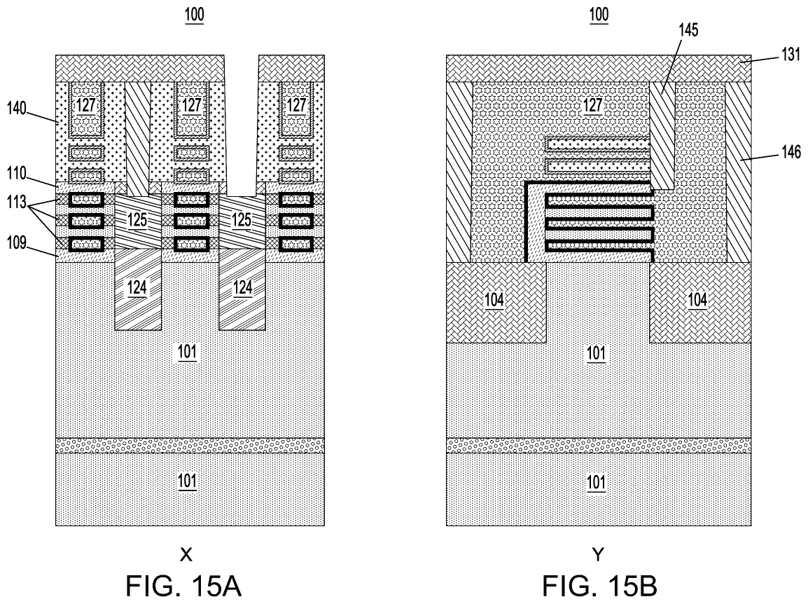

FIGS. 15A and 15B show cross-sectional views, which respectively correspond to the lines X and Y in FIG. 1, of the semiconductor structure 100 following middle-of-line (MOL) deep contact patterning, according to an illustrative embodiment. An additional ILD layer 131 is formed on top of the semiconductor structure 100. An opening is formed through the additional ILD layer 131, the second metal electrode layer 140, and the BDI layer 109 to expose a top surface of a corresponding bottom source/drain region 125 on which a frontside source/drain contact 150 is to be formed. According to an embodiment, masks are formed on parts of the additional ILD layer 131, and an exposed portion of the additional ILD layer 131 followed by removal of the portion of the second metal electrode layer 140 corresponding to where the opening is to be formed are removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

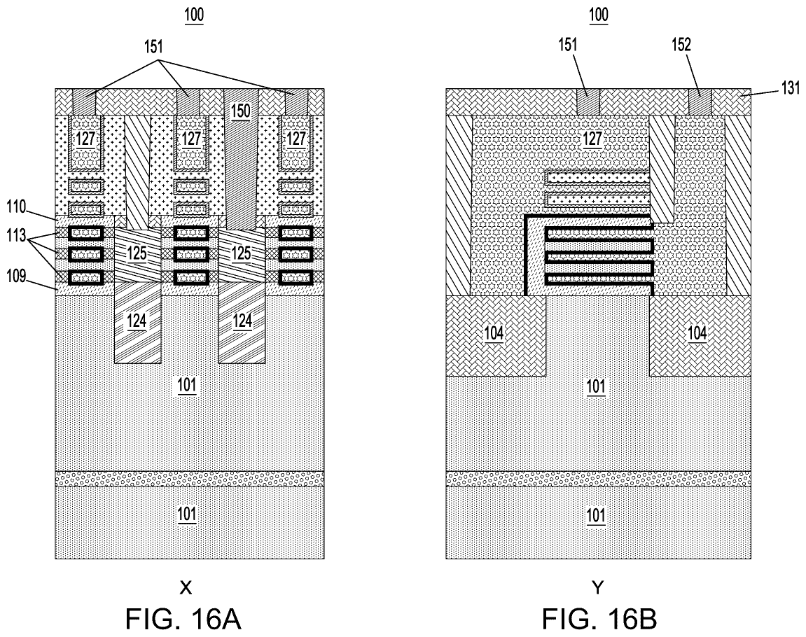

FIGS. 16A and 16B show cross-sectional views, which respectively correspond to the lines X and Y in FIG. 1, of the semiconductor structure 100 following MOL shallow contact and gate patterning and metallization, according to an illustrative embodiment. Shallow openings are formed through the additional ILD layer 131 to expose corresponding top surfaces of the first metal electrode layer 127, on which shallow electrode contacts 151 and gate contact 152 are to be formed. The shallow opening can be formed using similar processes as described for the opening where the frontside source/drain contact 150 is to be formed. The frontside source/drain contact 150 connects the bottom source/drain region 125 to the top MIM capacitor.

Metal layers are deposited in the deep and shallow openings to form the frontside source/drain contact 150, the shallow electrode contacts 151, and the gate contact 152. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process, such as CMP, to remove excess portions of the metal layers from on top of the additional ILD layer 131.

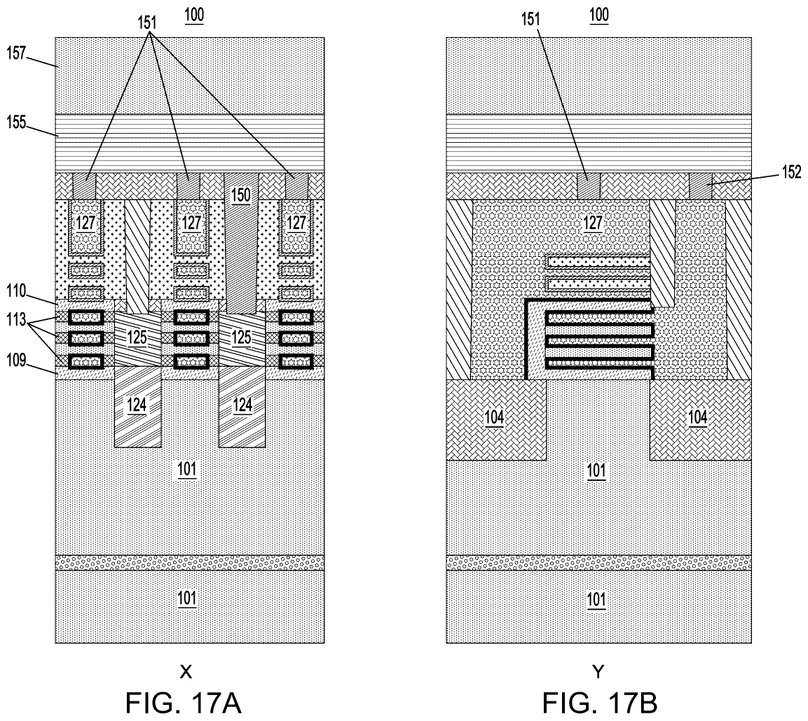

FIGS. 17A and 17B show cross-sectional views, which respectively correspond to the lines X and Y in FIG. 1, of the semiconductor structure 100 following frontside back-end-of-line (BEOL) interconnect formation and carrier wafer bonding, according to an illustrative embodiment. Frontside BEOL interconnects 155 are formed on the additional ILD layer 131 including the metal layers 150, 151, and 152. A carrier wafer 157 is bonded to the frontside BEOL interconnects 155. The frontside BEOL interconnects 155 include various BEOL interconnect structures that may electrically connect to the metal layers 150, 151, and 152. The carrier wafer 157 may be formed of materials similar to those of the semiconductor substrate 101 and may be formed over the frontside BEOL interconnects 155 using a wafer bonding process, such as dielectric-to-dielectric bonding.

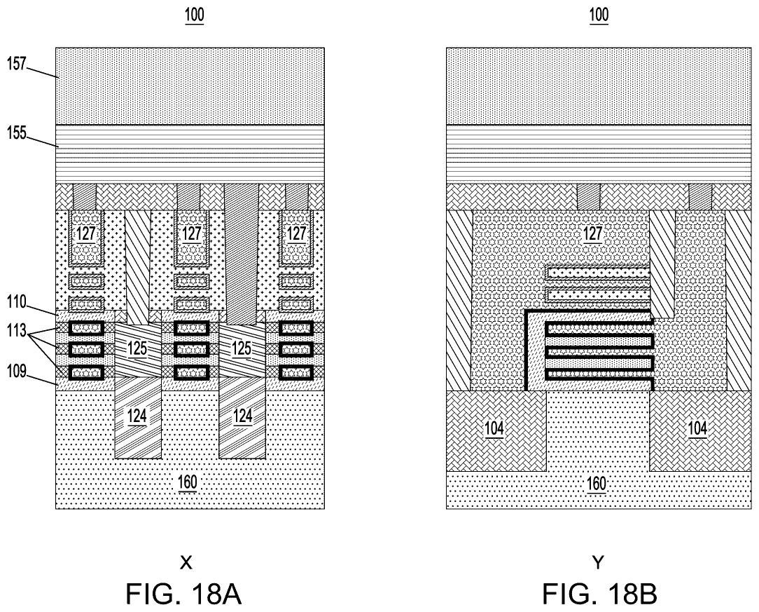

FIGS. 18A and 18B show cross-sectional views, which respectively correspond to the lines X and Y in FIG. 1, of the semiconductor structure 100 following wafer flipping, semiconductor substrate removal, etch stop layer removal, and backside ILD layer formation, according to an illustrative embodiment. Using the carrier wafer 157, the semiconductor structure 100 may be “flipped” (for example, rotated 180 degrees) so that the structure is inverted. In addition, the semiconductor substrate 101 is removed from the backside of the semiconductor structure 100, including the etch stop layer 102. For example, the semiconductor substrate 101 is etched with an etchant that selectively etches silicon with respect to a material of the etch stop layer 102. The etching processes for removal of the etch stop layer 102 include, for example, IBE by Ar/CHF3 based chemistry. Etchants for removing the semiconductor substrate 101 include, for example, potassium hydroxide (KOH) and TMAH.

A backside ILD layer 160 is deposited using deposition techniques such as, for example, CVD, PECVD, RFCVD, PVD, ALD, MBD, PLD, and/or LSMCD, followed by a planarization process such as CMP. The backside ILD layer 160 may comprise, for example, SiOₓ, SiOC, SiOCN or some other dielectric.

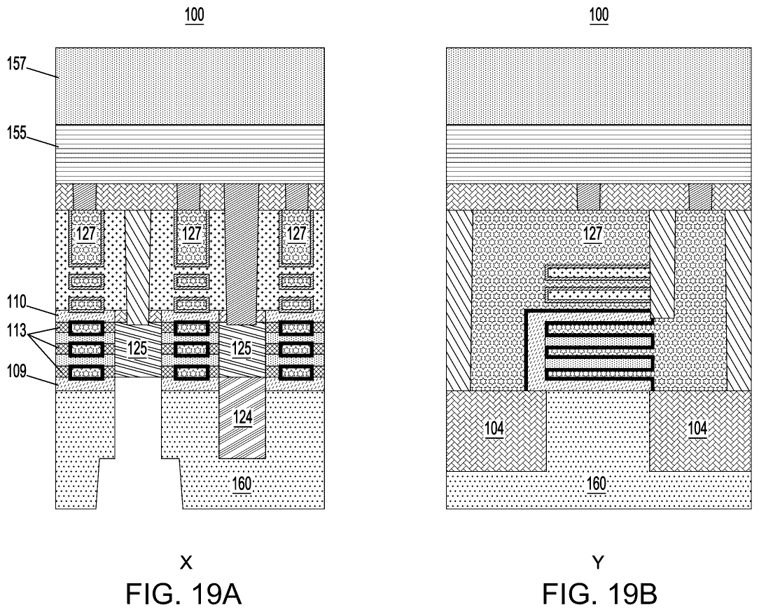

FIGS. 19A and 19B show cross-sectional views, which respectively correspond to the lines X and Y in FIG. 1, of the semiconductor structure 100 following backside contact patterning and placeholder removal, according to an illustrative embodiment. The backside contact patterning can include depositing a mask with openings where the backside source/drain contact is to be formed, and then selectively removing the exposed portions of the backside ILD layer 160 using, for example, a dry etching process using a RIE or IBE process, a wet chemical etching process, or a combination of these etching processes. The exposed portions of the backside ILD layer 160 can be removed to expose the bottom portions of the sacrificial placeholders 124. The exposed sacrificial placeholder 124 can be selectively removed to expose backside portions of the bottom source/drain regions 125. The sacrificial placeholder 124 can be removed using, for example, a selective dry or wet etch process.

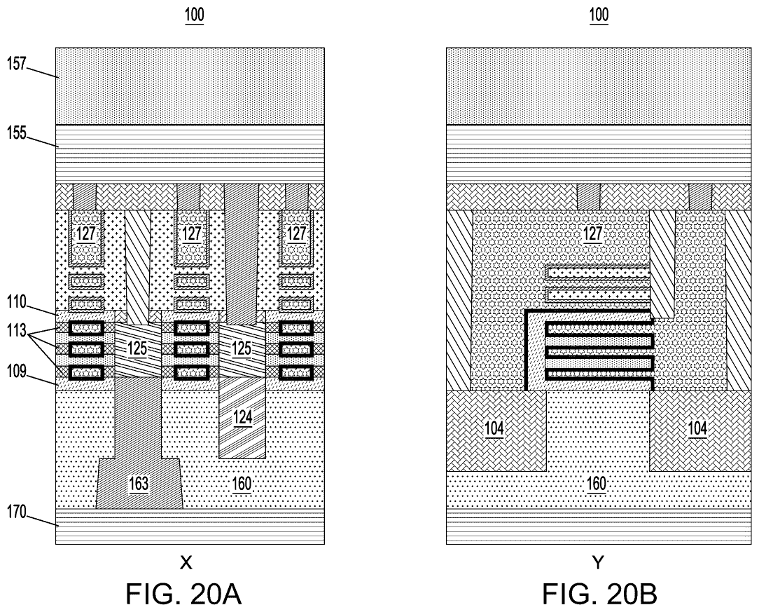

FIGS. 20A and 20B show cross-sectional views, which respectively correspond to the lines X and Y in FIG. 1, of the semiconductor structure 100 following backside contact and backside interconnect formation, according to an illustrative embodiment. A backside source/drain contact 163 is formed by filling and planarizing of contact material. The contact material of the backside source/drain contact 163 may be similar to that of the frontside metal layers 150, 151, and 152, for example. The backside source/drain contact 163 contacts a backside of the source/drain region 125.

Backside BEOL layers 170 (also referred to herein as backside interconnects) are formed on the backside ILD layer 160 and on the backside source/drain contact 163. The backside BEOL layers 170 can include various backside power delivery network structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. The backside source/drain contact 163 is connected to the backside BEOL layers 170. In some embodiments, the backside BEOL layers 170 can alternatively or additionally be used for routing of signals, including power and/or clock signals as non-limiting examples.

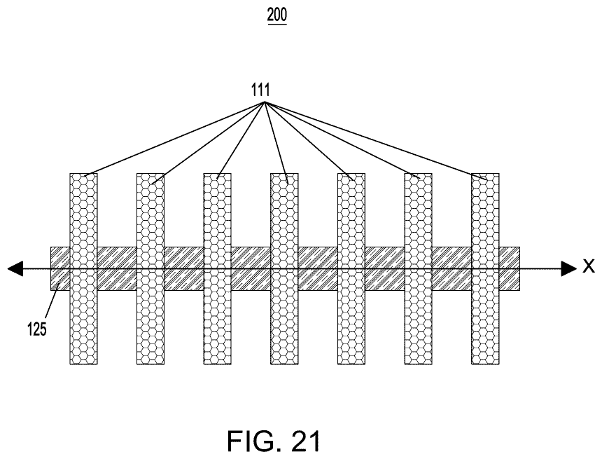

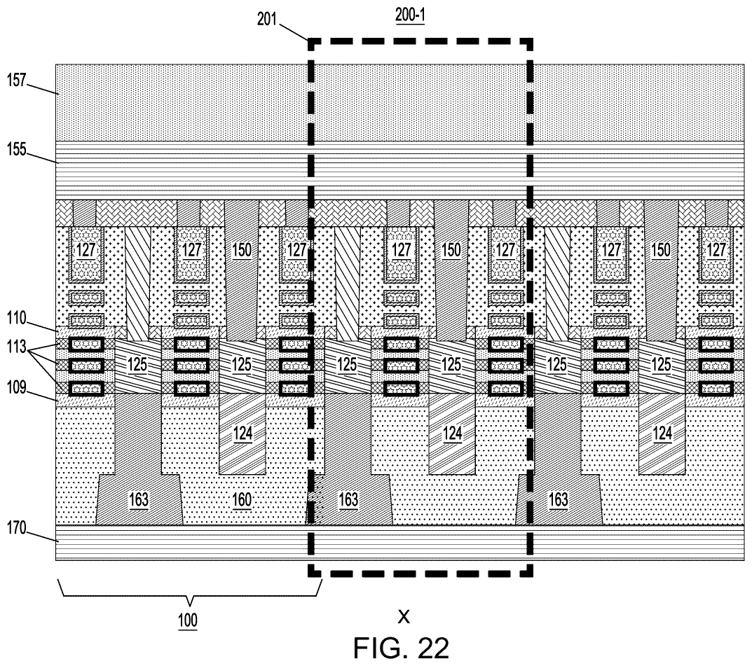

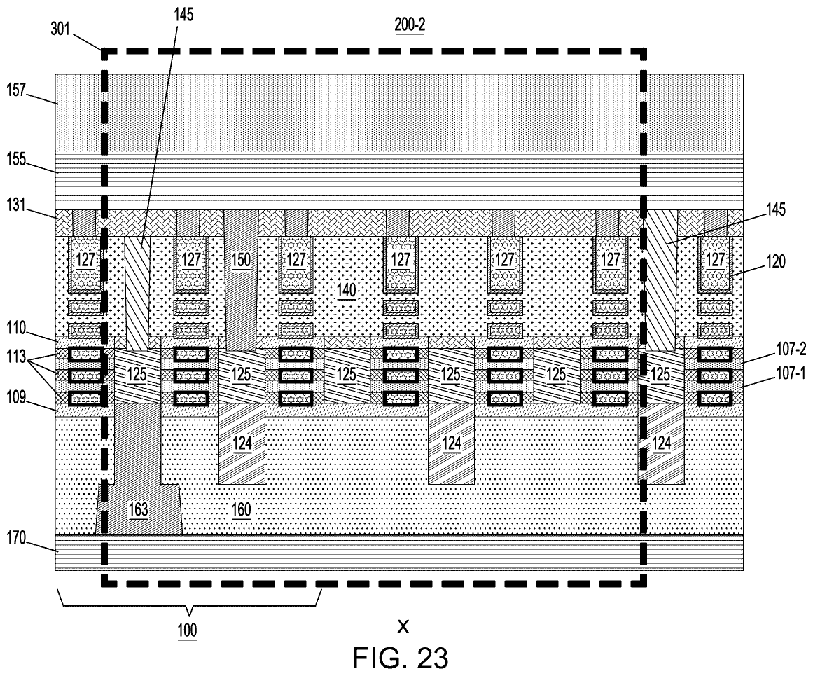

It is to be appreciated the that the process depicted in FIGS. 1-20B can be used to form arrays of stacked transistors and capacitors. For example, FIG. 21 depicts a top view of a semiconductor structure 200 with line X on which the cross-sectional views of FIGS. 22-23 are based, according to illustrative embodiments. It is noted that the same or similar reference numbers from FIGS. 1-20B are used in FIGS. 21-23 to denote the same or similar features, elements, or structures, and thus, a detailed explanation of the same or similar features, elements, or structures is not repeated. FIG. 21 shows a semiconductor structure 200 that is similar to the semiconductor structure 100 except with seven dummy gate portions 111.

FIG. 22 depicts a cross-sectional view corresponding to the line X in FIG. 21 of a first embodiment (denoted 200-1) of the semiconductor structure 200. A first portion of the semiconductor structure 200-1 corresponds to the semiconductor structure 100 shown in FIG. 20A. In this example, the portion 201 corresponds to a unit cell including one transistor and two capacitors, referred to as a 1T2C unit cell.

FIG. 23 depicts a cross-sectional view corresponding to the line X in FIG. 21 of a second embodiment (denoted 200-2) of the semiconductor structure 200. Similar to FIG. 22, a first portion of the semiconductor structure 200-2 corresponds to the semiconductor structure 100 shown in FIG. 20A. In this example, the portion 301 corresponds to a unit cell including one transistor and five capacitors connected in parallel, referred to as a 1T5C unit cell. The embodiments shown in FIGS. 22-23 are merely examples, and those skilled in the art will appreciate that semiconductor devices having various other types of unit cells can be formed using the techniques described herein, such as a unit cell with one transistor and two or more capacitors.

Embodiments described herein provide a stacked structure having a MIM capacitor vertically stacked on a transistor. Such a stacked structure can advantageously provide improved scalability. Additionally, a direct backside source/drain contact (e.g., the backside source/drain contact 163 shown in FIG. 20A) enables improved routing for backside power delivery network (BSPDN) implementations. Combining a MIM capacitor and a transistor in a vertically stacked structure can also improve functional density while reducing the overall footprint of the semiconductor device relative to conventional techniques.

In one embodiment, a semiconductor device includes at least one metal-insulator-metal capacitor device, where the metal-insulator-metal capacitor device includes a first electrode, an insulator material surrounding the first electrode, and a second electrode surrounding the insulator material. The semiconductor device also includes at least one transistor device vertically adjacent to the at least one metal-insulator-metal capacitor device, and a first middle-of-line contact connecting the first electrode to a first source/drain region associated with the at least one transistor device and to at least one first frontside interconnect structure.

In embodiments, the semiconductor device may include a second middle-of-line contact connecting the second electrode of the at least one metal-insulator-metal capacitor device to at least one second frontside interconnect structure.

In embodiments, the semiconductor device may include a direct backside source/drain contact connecting at least one second source/drain region associated with the at least one transistor device to one or more backside interconnect structures.

In embodiments, the semiconductor device may include a placeholder disposed beneath the first source/drain region associated with the at least one transistor device.

In embodiments, the semiconductor device may include a first self-aligned dielectric layer disposed between the at least one metal-insulator-metal capacitor device and the at least one transistor device, where the first self-aligned dielectric layer electrically isolates the metal-insulator-metal capacitor device from the at least one transistor device.

In embodiments, the semiconductor device may include a shallow gate separation region that electrically isolates the first electrode and the second electrode from a gate structure of the at least one transistor device, where the shallow gate separation region contacts vertical sides of at least two stacked horizontal portions of the first electrode and a first vertical side of the first self-aligned dielectric layer.

In embodiments, the semiconductor device may include a spacer that electrically isolates the second electrode from the gate structure of the at least one transistor device.

In embodiments, the spacer may contact vertical sides of one or more channel layers of the at least one transistor device and a second vertical side of the first self-aligned dielectric layer.

In embodiments, the semiconductor device may include a second self-aligned dielectric layer disposed below the at least one transistor device that electrically isolates a gate structure associated with the at least one transistor device from a backside interlayer dielectric.

In embodiments, the semiconductor device may include at least one deep gate separation region adjacent to the at least one transistor device vertically adjacent to the at least one metal-insulator-metal capacitor device.

In embodiments, the at least one deep gate separation region may electrically isolate the first electrode of the at least one metal-insulator-metal capacitor device from at least one adjacent metal-insulator-metal capacitor device.

In embodiments, the at least one deep gate separation region may electrically isolate a gate structure of the at least one transistor device from the gate structure of at least one adjacent transistor device.

In embodiments, the semiconductor device may include a unit cell including the at least one metal-insulator-metal capacitor device, the at least one transistor device, and one or more additional metal-insulator-metal capacitor devices adjacent to the at least one metal-insulator-metal capacitor device.

In another embodiment, a semiconductor device includes a transistor device associated with first and second source/drain regions, a capacitor device vertically adjacent to the transistor device. The capacitor device includes a first electrode, an insulator material surrounding the first electrode, and a second electrode surrounding the insulator material, where the first electrode comprises one or more stacked first portions and at least one second portion that is larger than each of the one or more first portions. The semiconductor device also includes a middle-of-line contact connecting the first electrode to the first source/drain region.

In embodiments, the semiconductor device may include a direct backside source/drain contact connecting the transistor device to the second source/drain region.

In embodiments, the semiconductor device may include a self-aligned dielectric layer disposed between the capacitor device and the transistor device, a shallow gate separation region separating the first electrode and the second electrode from a gate structure of the transistor device, and a spacer separating the second electrode from the gate structure of the transistor device.

In embodiments, the semiconductor device may include at least one deep gate separation region adjacent to the transistor device and at least one metal-insulator-metal capacitor device. The at least one deep gate separation region may separate at least one of the first electrode from at least one electrode of an adjacent capacitor device and a gate structure of the transistor device from a gate structure of at least one adjacent transistor device.

In another embodiment, a method includes forming a capacitor device in a first portion of a stacked nanosheet structure, where the capacitor device comprises a first electrode, an insulator material surrounding the first electrode, and a second electrode surrounding the insulator material. The method includes forming a transistor device in a second portion of the stacked nanosheet structure including one or more channel layers, where the first portion is positioned above the second portion of the nanosheet structure. The method also includes forming a direct backside source/drain contact that connects a first source/drain region of the transistor device to one or more backside interconnect structures.

In embodiments, the method may include forming a first middle-of-line contact that connects the first electrode to a second source/drain region associated with the transistor device and to one or more frontside interconnect structures.

In embodiments, the method may include forming a second middle-of-line contact that connects the second electrode to one or more frontside interconnect structures.

Semiconductor devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
at least one metal-insulator-metal capacitor device, wherein the metal-insulator-metal capacitor device comprises a first electrode, an insulator material surrounding the first electrode, and a second electrode surrounding the insulator material;
at least one transistor device vertically adjacent to the at least one metal-insulator-metal capacitor device; and
a first middle-of-line contact connecting the first electrode to a first source/drain region associated with the at least one transistor device and to at least one first frontside interconnect structure.

2. The semiconductor device of claim 1, further comprising:
a second middle-of-line contact connecting the second electrode of the at least one metal-insulator-metal capacitor device to at least one second frontside interconnect structure.

3. The semiconductor device of claim 1, further comprising:
a direct backside source/drain contact connecting at least one second source/drain region associated with the at least one transistor device to one or more backside interconnect structures.

4. The semiconductor device of claim 1, further comprising:
a placeholder disposed beneath the first source/drain region associated with the at least one transistor device.

5. The semiconductor device of claim 1, further comprising:
a first self-aligned dielectric layer disposed between the at least one metal-insulator-metal capacitor device and the at least one transistor device, wherein the first self-aligned dielectric layer electrically isolates the metal-insulator-metal capacitor device from the at least one transistor device.

6. The semiconductor device of claim 5, further comprising:
a shallow gate separation region that electrically isolates the first electrode and the second electrode from a gate structure of the at least one transistor device, wherein the shallow gate separation region contacts vertical sides of at least two stacked horizontal portions of the first electrode and a first vertical side of the first self-aligned dielectric layer.

7. The semiconductor device of claim 6, further comprising:
a spacer that electrically isolates the second electrode from the gate structure of the at least one transistor device.

8. The semiconductor device of claim 7, wherein the spacer contacts vertical sides of one or more channel layers of the at least one transistor device and a second vertical side of the first self-aligned dielectric layer.

9. The semiconductor device of claim 5, further comprising:
a second self-aligned dielectric layer disposed below the at least one transistor device that electrically isolates a gate structure associated with the at least one transistor device from a backside interlayer dielectric.

10. The semiconductor device of claim 1, further comprising:
at least one deep gate separation region adjacent to the at least one transistor device vertically adjacent to the at least one metal-insulator-metal capacitor device.

11. The semiconductor device of claim 10, wherein the at least one deep gate separation region electrically isolates the first electrode of the at least one metal-insulator-metal capacitor device from at least one adjacent metal-insulator-metal capacitor device.

12. The semiconductor device of claim 10, wherein the at least one deep gate separation region electrically isolates a gate structure of the at least one transistor device from a gate structure of at least one adjacent transistor device.

13. The semiconductor device of claim 1, further comprising:
a unit cell comprising the at least one metal-insulator-metal capacitor device, the at least one transistor device, and one or more additional metal-insulator-metal capacitor devices adjacent to the at least one metal-insulator-metal capacitor device.

14. A semiconductor device comprising:
a transistor device associated with first and second source/drain regions;
a capacitor device vertically adjacent to the transistor device, the capacitor device comprising a first electrode, an insulator material surrounding the first electrode, and a second electrode surrounding the insulator material, wherein the first electrode comprises one or more stacked first portions and at least one second portion that is larger than each of the one or more stacked first portions; and
a middle-of-line contact connecting the first electrode to the first source/drain region.

15. The semiconductor device of claim 14, further comprising:
a direct backside source/drain contact connecting the transistor device to the second source/drain region.

16. The semiconductor device of claim 14, further comprising:
a self-aligned dielectric layer disposed between the capacitor device and the transistor device;
a shallow gate separation region separating the first electrode and the second electrode from a gate structure of the transistor device; and
a spacer separating the second electrode from the gate structure of the transistor device.

17. The semiconductor device of claim 14, further comprising:
at least one deep gate separation region adjacent to the transistor device, wherein the at least one deep gate separation region separates at least one of:
the first electrode from at least one electrode of an adjacent capacitor device; and
a gate structure of the transistor device from a gate structure of at least one adjacent transistor device.

18. A method, comprising:
forming a capacitor device in a first portion of a stacked nanosheet structure, wherein the capacitor device comprises a first electrode, an insulator material surrounding the first electrode, and a second electrode surrounding the insulator material;
forming a transistor device in a second portion of the stacked nanosheet structure comprising one or more channel layers, wherein the first portion is positioned above the second portion of the stacked nanosheet structure; and
forming a direct backside source/drain contact that connects a first source/drain region of the transistor device to one or more backside interconnect structures.

19. The method of claim 18, further comprising:
forming a first middle-of-line contact that connects the first electrode to a second source/drain region associated with the transistor device and to one or more frontside interconnect structures.

20. The method of claim 18, further comprising:
forming a second middle-of-line contact that connects the second electrode to one or more frontside interconnect structures.
